(19) United States
(12) Patent Application Publication
(10) Pub. No.: US 2023/0182181 A1
(43) Pub. Date: Jun. 15, 2023

(54) System and Method for Cleaning Carrier

(71) Applicant: Pintek Solutions Corporation, Lewes, DE (US)

(72) Inventors: Yi-Chuan PENG, Hsinchu City (TW); Ko-Hsi CHAN, Hsinchu City (TW); Shih Tsung CHEN, Hsinchu City (TW)

(21) Appl. No.: 17/919,594

(22) PCT Filed: Mar. 9, 2022
(86) PCT No.: PCT/US22/19453

§ 371 Date: Oct. 18, 2022

Related U.S. Application Data
(60) Provisional application No. 63/159,671, filed on Mar. 11, 2021.

(51) Int. Cl. B08B 9/28; B08B 9/34

(52) U.S. Cl. CPC B08B 9/283; B08B 9/34; B08B 2209/08

(57) ABSTRACT

This invention provides a method and a system for cleaning a container for storing wafers or masks. A contained with lid is washed directly after the container is loaded with lid opened in the cleaning system. Gas exchange rate in the washing station can be increased such that particles or AMC inside the container or attached to the lid can be carried out more easily. Then, contamination-free gas is purged to the container as well as lid in a high temperature environment. A vacuum station can be optionally adapted between the washing station and the contamination-free gas purging station to enhance the cleanliness of the container.

### FIELD OF THE INVENTION

The invention relates to a system and method for cleaning a container, and more particularly to a system and method for cleaning a FOUP in a heated environment.

### BACKGROUND OF THE INVENTION

In the current semiconductor manufacturing process, cleanliness requirement is extremely rigorous, and wafers are thus stored in a clean mini environment container, FOUP.

FOUP will be contaminated after wafers experience semiconductor manufacturing processes and are stored in the FOUP. Hence, FOUP must be cleaned regularly after certain semiconductor processes in order to keep high semiconductor manufacturing yield.

In the FOUP cleaning process, particles or AMC (Airborne Molecular Contamination) must be removed out completely. Airborne Molecular Contamination (AMC) is chemical contamination in the form of vapors or aerosols that has a detrimental effect on a product or a process. There are four categories defined by SEMI (Semiconductor Equipment and Materials International), which includes molecular acid(MA), molecular base(MB), molecular condensable(MC), and molecular dopants(MD). These chemicals may be organic or inorganic in nature and includes acids, bases, polymer additives, organometallic compounds and dopants. The main sources for AMC are building and cleanroom construction materials, general environment, process chemicals and operating personnel. How to remove AMC as well as particles in the FOUP is thus a critical issue in FOUP cleaning process.

Current FOUP cleaning system includes a washing station, a vacuum station, and a nitrogen purging station. FOUP is always evacuated after the washing step to remove particles or AMC. In the current commercial cleaning system, only three minutes for the FOUP evacuation process, wherein there is no robot operation cycle time included. The cleaning process is too long due to this vacuum step. Furthermore, in some studies and investigations, thirty minutes are required to completely and effectively remove out all particles and AMCs. Thus, to fulfil the cleanliness requirement will deteriorate the FOUP cleaning cycle time.

The vacuum station will incur complex mechanical structures and parts, such that purchase cost and operation cost are raised, and the footprint will be increased due to vacuum station, and operation cost is thus raised.

Temperatures from the washing step to the evacuation step are kept at high temperature in the current cleaning system. While the FOUP is transferred from the vacuum station to the unload port to be purged by nitrogen gas, the environment will be kept at the temperature in the clean room, such as 21° C. This is a cooling process and surface of the FOUP will be contracted and AMC will be grasped. The purpose for purging nitrogen gas is thus failed.

More deterioration, AMC will be released in the later semiconductor process. The semiconductor manufacturing yield will be affected seriously, especially for the semiconductor node below 10 nm.

Thus, an invention is necessary to solve the issues mentioned above.

BRIEF SUMMARY OF THE INVENTION

The object of this invention is to provide a FOUP cleaning system and method at high temperature environment, such that AMC can be removed more seriously.

It is an object of this invention that the FOUP can be cleaned with or without evacuating process.

It is an object of the present invention to provide a washing chamber with high temperature.

It is an object of the present invention to wash FOUP by using hot DI water.

It is an object of the present invention to provide high exchange rate in the washing process.

It is an object of the present invention to purge FOUP with hot contamination-free gas.

Accordingly, the invention provides a method for cleaning a container, which comprises steps of loading a container into a cleaning system; opening a lid of the container; washing the container and the lid at a first temperature higher than 45° C.; and purging the container with contamination-free gas at temperature at least higher than 45° C.

In the method according to one embodiment of the present invention, the washing step includes steps of spraying DI water to the container and the lid; and purging gas to the container and the lid to dry the container and the lid.

In the method according to one embodiment of the present invention, the purging gas step provides a gas exchange rate at least 8 cycle/min

In the method according to one embodiment of the present invention, a temperature of the washing chamber is ranged from about 45-70° C.

In the method according to one embodiment of the present invention, a temperature of the DI water is ranged from about 45-70° C.

In the method according to one embodiment of the present invention, the method further comprises an evacuating step between said washing step and said nitrogen purging step for evacuating the container.

In the method according to one embodiment of the present invention, a temperature of the evacuating step is about 45° C.

In the method according to one embodiment of the present invention, the container is a FOUP.

In the method according to one embodiment of the present invention, the method further comprises a step of purging the FOUP with contamination-free gas at a clean room temperature.

The present invention also provides a system for cleaning a container, which comprises a load port for loading the container and opening a lid of the container, a washing chamber, an unload port, and a heating element. The washing chamber, for washing the container with a first nuzzle and a second nuzzle, receives the container and the lid from the load port, wherein the first nuzzle sprays a beam of DI water to the container and the lid, and a second nuzzle purges a gas flow to dry the container. The unload port receives the container from the washing chamber, for purging the container with contamination-free gas. The heating element for controlling temperatures of the washing chamber, the first nuzzle, the second nuzzle, and the contamination-free gas.

In the system according to one embodiment of the present invention, the second nuzzle provides a gas exchange rate at least 8 cycle/min.

In the system according to one embodiment of the present invention, the temperature of the washing chamber is kept above 45° C.

In the system according to one embodiment of the present invention, the temperature of the beam of DI water is kept above 45° C.

In the system according to one embodiment of the present invention, the temperature of the second nuzzle is kept above 45° C.

In the system according to one embodiment of the present invention, the temperature of the nitrogen gas is kept above 45° C.

In the system according to one embodiment of the present invention, the system further comprises a vacuum chamber for receiving the container and the lid from the washing chamber to evacuating the container and the lid.

In the system according to one embodiment of the present invention, the heating element control a temperature of the vacuum chamber.

In the system according to one embodiment of the present invention, the temperature of the vacuum chamber is kept above 45° C.

In the system according to one embodiment of the present invention, the container is a FOUP.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

Further advantages of the present invention may become apparent to those skilled in the art with the benefit of the following detailed descriptions of the preferred embodiments and upon reference to the accompanying drawings in which:

FIG. 1 is a schematic representation of a conventional FOUP cleaning system;

FIG. 2 is a flow diagram showing the steps for cleaning a FOUP in accordance with a conventional process;

FIG. 3 is a schematic representation of a FOUP cleaning system in accordance with an embodiment of the present invention;

FIG. 4 is a flow diagram showing the steps for cleaning a FOUP in accordance with an embodiment of the present invention;

FIG. 5 is a schematic representation of a FOUP cleaning system in accordance with another embodiment of the present invention; and

FIG. 6 is a flow diagram showing the steps for cleaning a FOUP in accordance with another embodiment of the present invention.

### DETAILED DESCRIPTION OF THE INVENTION

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention.

The following descriptions explain or interpret contents of terms in the present invention, such that embodiments of the present invention can be understood more clearly.

The terms “container”, “pod” or “box” is a hollow object that can be used for holding articles, especially to carry or store the articles.

The term “cassette” in the present invention may refer to a container within structures for storing or directly operating articles or objects. The term “wafer cassette” may be used for storing wafers dedicatedly.

The term “holder” in this invention may refer to a container for putting or keeping articles or objects therein.

The term “tray” in the present invention may refer to a flat container for carrying or storing articles or objects therein.

The term “carrier” in the present invention may refer to a container with handles for carrying articles or objects therein.

The term “SMIF(Standard Mechanical Interface)” in the present invention may refer to a system for semiconductor wafer fabrication and cleanroom environment. Now, SMIF is a SEMI standard.

The term “FOUP(Front Opening Unified Pod)” in the present invention may refer to a container for storing wafers or masks from one facility or equipment to another facility or equipment inside a factory.

The term “FOSB” in the present invention may refer to a container for storing wafers being shipped from one factory to another factory.

The term “MAC(multi application carrier)” in the present invention may refer to a container for storing semiconductor wafers, masks or reticles with multiple applications or purposes.

The term “high temperature” in the present invention may refer to a temperature higher than the temperature in the cleanroom.

The term “contamination-free gas” in the present invention refers to clean gas without contamination, such as nitrogen gas, CDA(Clean Dry Air), or extreme CDA(X-CDA).

The present invention may be applied to clean the containers, cassettes, holders, trays, carriers, SMIF pods, FOUPs, FOSBs for storing semiconductor wafers, reticles or masks in semiconductor manufacturing foundry.

In the present invention, temperature environment of the washing chamber will be raised more than 50° C., and preferred temperature will be between about 60-70° C. The increased temperature will boost AMC floating in the washing chamber to prevent from AMC adhering back to the surface of the FOUP.

In the present invention, temperature of the washing solution will be kept at least 45° C., which can be ranged from about 50-70° C., and preferred from about 50-60° C. The higher washing temperature is, the more possibility to remove out AMC from surfaces of FOUP wall.

In the present invention, gas exchange rate in the drying step of the washing procedure is increased from conventional 1 cycle/min to 4 cycle/min The increased gas exchanged rate, at least 8 cycle/min, will bring washed high dose AMC out of the washing chamber.

In the present invention, vacuum procedure can be optional. If ultra-cleanliness is required, vacuum station can be adapted in the cleaning system.

In the present invention, FOUP is thus purged by nitrogen gas in a high temperature, such as about 45° C., instead of conventional room temperature, for example 21° C., in the clean room.

In the present invention, an optional purging temperature step can be a gradually cooling process from 45° C. to room temperature of the clean room. The nitrogen gas in foundry, provided by factory service, is stored in the tank with high pressure as liquid nitrogen. When the liquid nitrogen is released to the washing facility with low pressure, temperature of the nitrogen gas is lowered than the cleanroom temperature. The nitrogen purge step in the conventional cleaning process will cool down the FOUP to a temperature lower than the cleanroom temperature, that AMC may be trapped on the surface of the FOUP at that lowered temperature. In foundry, nitrogen gas can be replaced by other contamination-free gas, such as CDA or X-CDA. Such contamination-free gas storage is similar to the nitrogen gas and may face similar issue.

In the present invention, one FOUP can be cleaned within 700 sec. Compared to conventional cleaning system, 900 sec is required to clean one FOUP.

In one embodiment of the present invention, while there is no vacuum station as well as the evacuation procedure, the same cleanliness requirement can be reached compared to the current commercial cleaning system. Thus, BOM(bill of materials) cost without vacuum chamber as well as vacuum pump and operational cost of the cleaning system of the present invention can be lowered. The cleaning duration is also lowered.

In the present invention, AMC can be removed out more effectively and completely, such that UPH(Unit Per Hour) in the semiconductor manufacturing process can be increased.

In the present invention, VOC(Volatile Organic Contamination) can be removed out more effectively and completely due to high temperature cleaning processes from washing procedure to the nitrogen purging procedure.

In the drawings, relative dimensions of each component and among every component may be exaggerated for clarity. Within the following description of the drawings the same or like reference numbers refer to the same or like components or entities, and only the differences with respect to the individual embodiments are described.

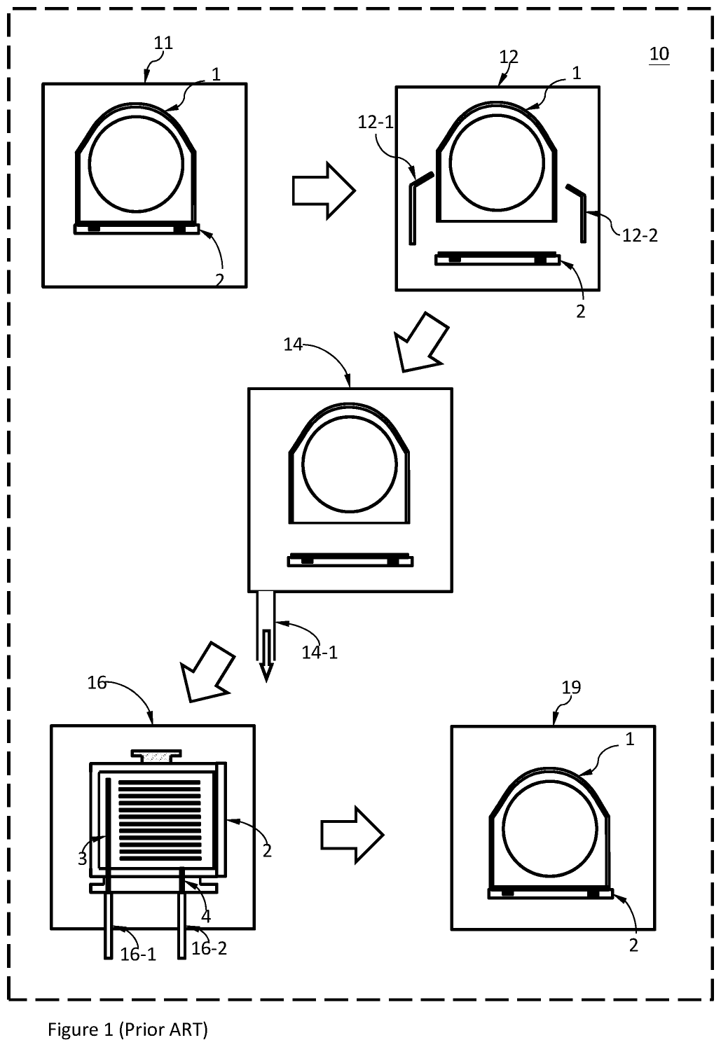

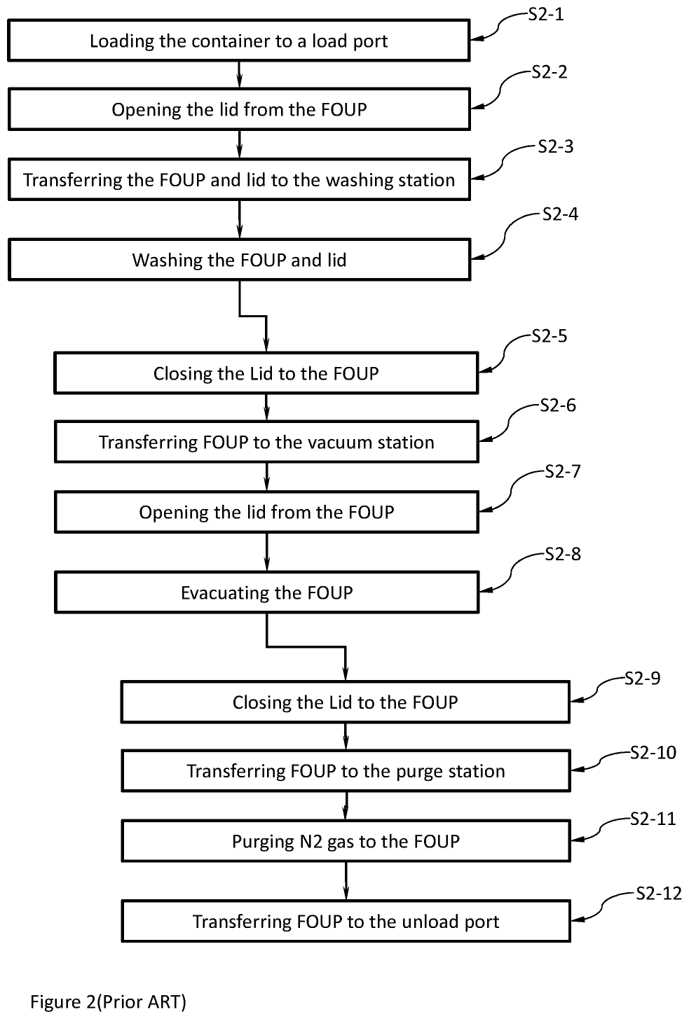

Please refer to FIG. 1, wherein a conventional cleaning system is provided. A conventional FOUP cleaning system 10 includes a load port 11, a washing chamber 12, a vacuum chamber 14, a nitrogen purging station 16, and an unload port 19. FIG. 2 is a flow diagram showing each step for cleaning FOUP in the FOUP cleaning system 10. In the beginning, a contaminated FOUP, including a body 1 and a lid or door 2, is loaded as shown in step S2-1. The lid 2 is thus opened from the body 1 as shown in step S2-2 in the load port 11 and then both the body 1 and lid 2 are transferred to the washing chamber 12 as shown in step S2-3. In the washing chamber 12, the body 1 and the lid 2 are washed by the washing nuzzle 12-1 and purged by the purging nuzzle 12-2 as shown in step S2-4. The washing nuzzle 12-1 will spray or purge a DI(de-ionized) water beam for washing internal side of the body 1. There may be two or more nuzzles for washing the body 1 more efficiently. A purging nuzzle 12-4 provides a gas flow to the body 1 for drying. Nitrogen gas flow or CDA(clean dry air) can be provided. Temperature in the washing chamber is kept at 50° C.

Then, the lid 2 is closed to the body 1 as shown in step S2-5 and both are transferred to the vacuum chamber 14 as shown in step S2-6. The lid 2 is opened again in the vacuum chamber 14 as shown in step S2-7, and then body 1 and lid 2 are evacuated in the vacuum chamber 14 through the evacuating pipe 14-1 about 3 minutes at 50° C. as shown in step S2-8.

Next, the FOUP is transferred to the nitrogen purging station. The lid 2 is closed to the body 1 as shown in step S2-9 in the vacuum chamber 14. The FOUP is transferred to the purging station 16 as shown in step S2-10. There are four holes at the bottom of the FOUP, two for gas inlet and two for gas outlet. Nitrogen gas is purged to the two gas inlets and then drawn out via the two gas outlets. Two nitrogen purging nuzzles 16-1 will extend two purging pipes 3 into the body 1 for purging nitrogen gas inside the body 1 and two nitrogen venting pipe 16-2 will extend two venting pipes 4 for venting nitrogen inside the body 1 as shown in step S2-11. The temperature in the purging station 16 is kept at room temperature of the clean room, such as 21° C. Then, the FOUP is transferred to the unload port 19 as shown in step S2-12.

Even if the nitrogen gas provided by the factory service can be kept at clean room temperature, the nitrogen purging step still lowers the temperature inside the FOUP. Because the lid 2 closed to the FOUP body 1 as shown in step S2-9 is at the vacuum chamber 14, inside the FOUP is close to vacuum. When the nitrogen gas is purged into the FOUP as shown in step S2-11, the nitrogen gas experiences pressure dropping process. At this time, the temperature inside the FOUP also drops according to the ideal gas law.

When the FOUP is transferred to the nitrogen purging station 16, the temperature of the FOUP itself will be cooled down from the high temperature in the vacuum chamber 14 to the room temperature of the clean room rapidly. The temperature difference is about 29° C. within several seconds in this station. Moreover, temperature of the nitrogen gas, due to the nitrogen liquid stored with high pressure from the factory service, may be lowered than the clean room temperature. Surfaces of the FOUP will be shrunk rapidly and AMC will be grasped. Thus, nitrogen purging procedure will not push or blow out the AMC from surfaces of the FOUP easily. In the worst case, AMC will be released from the surfaces of the FOUP during semiconductor manufacturing process, and fall on the wafer surfaces.

In the present invention, the temperature in the washing chamber is raised such that AMC can be activated more easily. Temperature of the nitrogen gas in the nitrogen purging station is also raised.

Detailed embodiments of the present invention can be described and shown herein with the drawings.

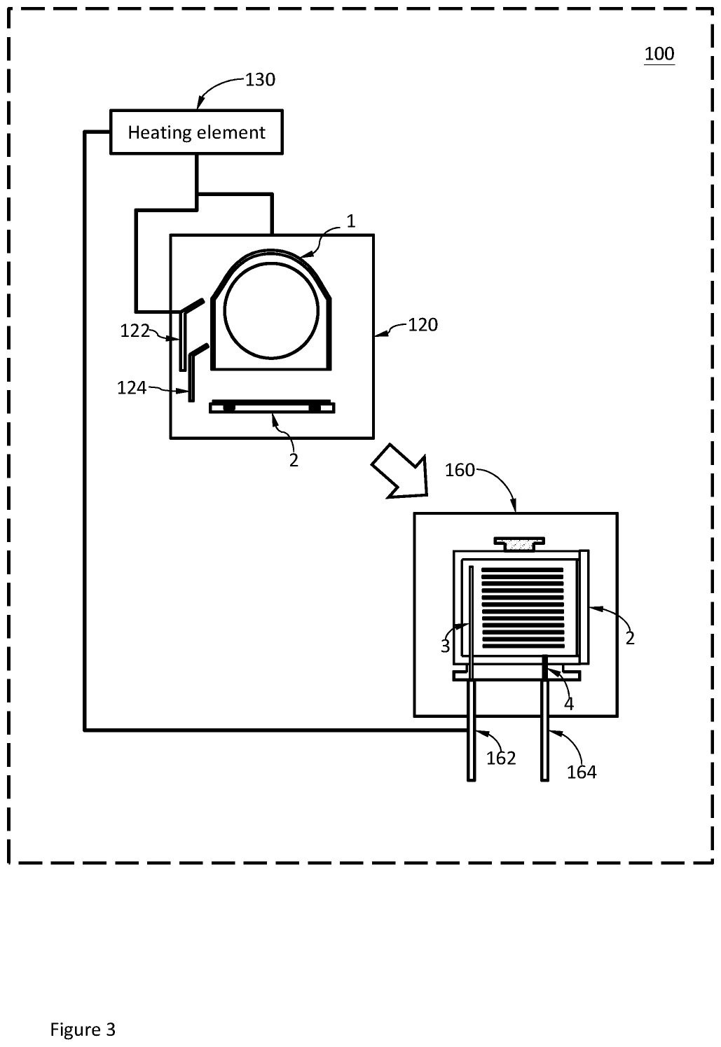

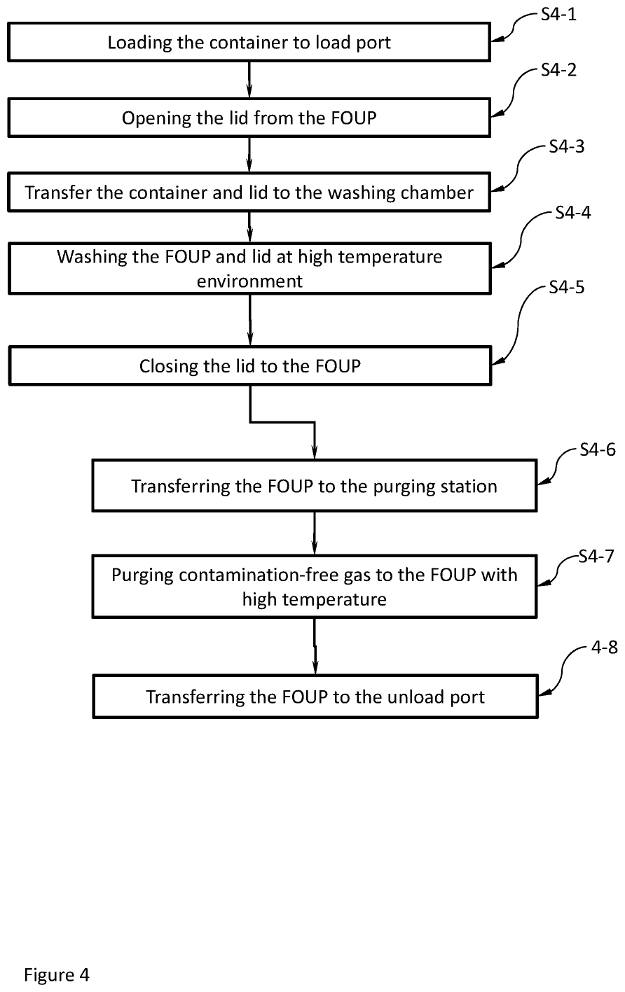

Please refer to FIG. 3 and FIG. 4, wherein FIG. 3 illustrates the FOUP cleaning system according to one embodiment of the present invention while FIG. 4 is a flow diagram showing each step for cleaning the FOUP in the cleaning system. In this embodiment, load port and unload port are not shown in order to illustrate the present invention more clearly. The cleaning system 100 includes a load port, a washing chamber 120, a nitrogen purging station 160, and an unload port. In the beginning, the FOUP or container is loaded into the load port as shown in step S4-1, and then the lid 2 is opened from the FOUP as shown in step S4-2. The body 1 and lid 2 are transferred to the washing chamber 120 as shown in step S4-3.

Then, body 1 and lid 2 of the FOUP are washed in the washing chamber 120 as shown in step S4-4. In this invention, a heating element 130 for generating and controlling heats to the washing chamber, washing nuzzle 122 and nitrogen purging nuzzle 162. In this embodiment, walls of the washing chamber 120 are heated by the heating element 130, so the temperature of the washing chamber can be controlled. Temperature of the washing chamber is kept at least 45° C., better 50° C., and preferred between 60-70° C. In one embodiment, a preferred temperature is about 65° C. Higher temperature in the washing chamber 120 may cause the VOC and AMC being washed out more easily, because all particles, including VOC and AMC, should get more energy at higher temperature. The AMC at higher temperature will be impinged by air within the washing chamber 120 more frequently, because the higher temperature, the effect of the Brown motion can be more obvious. Thus, some particles may be removed from the FOUP walls.

Hot DI water, with temperature above 45° C., is provided to wash the FOUP body 1 and lid 2. Hot DI water is another better condition for removing the VOC and AMC. The temperature of the DI water can be larger than 50° C., and preferred between 50-70° C. Even if the particles still attach on the FOUP walls, the hot DI water thus can remove most particles on the FOUP, when the temperature of the DI water is heated. Similar to the heated washing chamber 120, the hot DI water will have more energy to remove most particles on the FOUP walls.

Higher gas exchange rate, in the present invention, is provided to dry to the FOUP body 1 and lid 2 in the washing chamber 120. The gas can be nitrogen or CDA(clean dry air) and purged from the purging nuzzle 124. The gas exchange rate can be at least 12 cycle/min One purpose of raising the gas exchange rate is to removing particles from the washing chamber 120 immediately, to avoid re-attach the FOUP walls. Then, the lid 2 is closed to the FOUP body 1 as shown in step S4-5.

The FOUP is transferred to the purging station 160, which is also the unload port, as shown in step S4-6. Then, contamination-free gas, such as nitrogen gas, CDA or X-CDA, is purged to the FOUP with high temperature, as shown in step S4-7. Two purging nuzzles 162 extend two purging pipes 3 into the FOUP through two holes of the FOUP, and two venting pipes 164 extend two venting pipes 4 into the FOUP through two holes of the FOUP. Contamination-free gas is provided from the purging nuzzles 162 to the purging pipes 3, while the venting pipes 4 vents gas inside the FOUP.

In this station, nitrogen gas is provided from the factory service, which is stored as liquid state with high pressure. The liquid nitrogen has a temperature below −196° C., and is heated to provide nitrogen gas in pipeline systems in a factory. However, the nitrogen gas always has lower temperature than the clean room temperature. If the nitrogen gas is purged to the FOUP directly from the factory service, the AMC inside the FOUP may take chance to attach to the FOUP wall again. Hence, in the present invention the nitrogen gas is heated by the heating element 130 and kept at 45° C. The two purging nuzzles 162 are heated by the heating element 130 in a first time duration, and then the heating element 130 stops heating the two purging nuzzles 162 in a second time duration. In one embodiment, the first time duration is larger than the second time duration. In some other embodiment, the heating element 130 can provide other ways to cool down the purging nuzzles 162, such as gradually lowering the temperature of the purging nuzzles 162 to the clean room temperature in linear or curvature modes.

In one embodiment, if CDA or X-CDA is applied as the contamination-free gas, similar process is also necessary, because CDA or X-CDA is stored in liquid phase also.

In this embodiment, there is no evacuating process, inside the FOUP is not vacuum when the FOUP is transferred to the purging station. The purged nitrogen gas will not experience pressure dropping process, and the temperature inside the FOUP will not drop.

Next, the FOUP is transferred to the unload port and unloaded as shown in step S4-8.

In this embodiment, the vacuum step can be omitted if the cleanliness requirement of the washed FOUP is acceptable. Thus, the present invention can provide high throughput for the FOUP cleaning process. In the semiconductor manufacturing processes, some FOUPS are applied to the front-end process, wherein the FOUP is not so dirty, and this invention can be applied. However, if the FOUP is applied to the back-end process, the FOUP should be washed more serious. Moreover, if the semiconductor process node continues to 5nm or below, ultra cleanliness is required. Thus, vacuum chamber can be applied to the present invention.

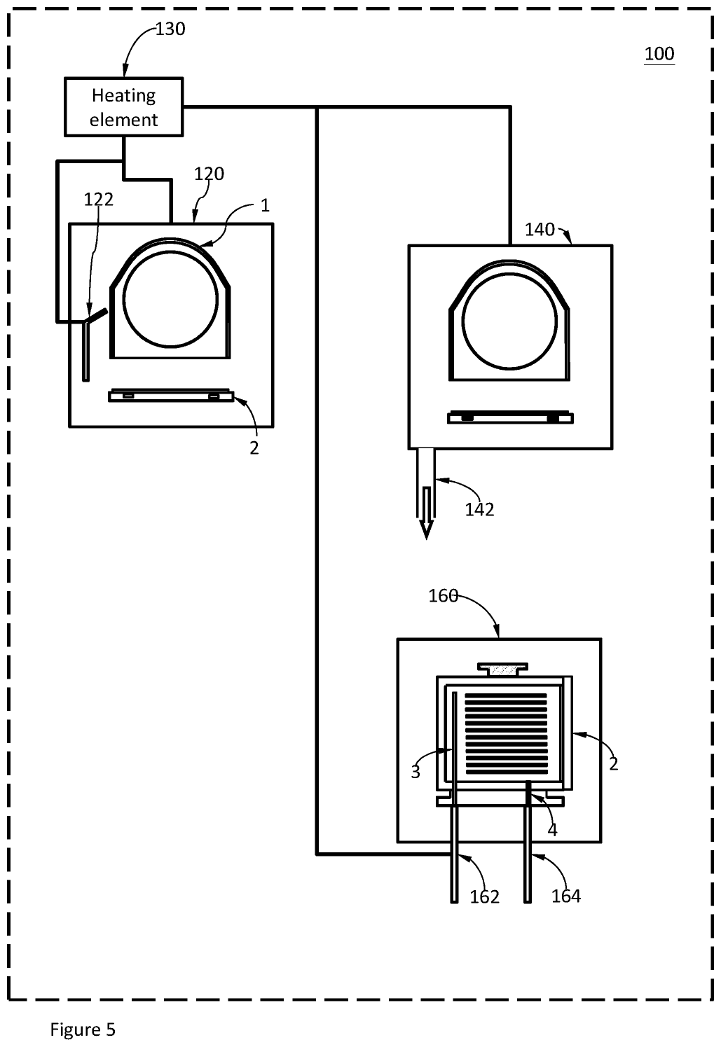

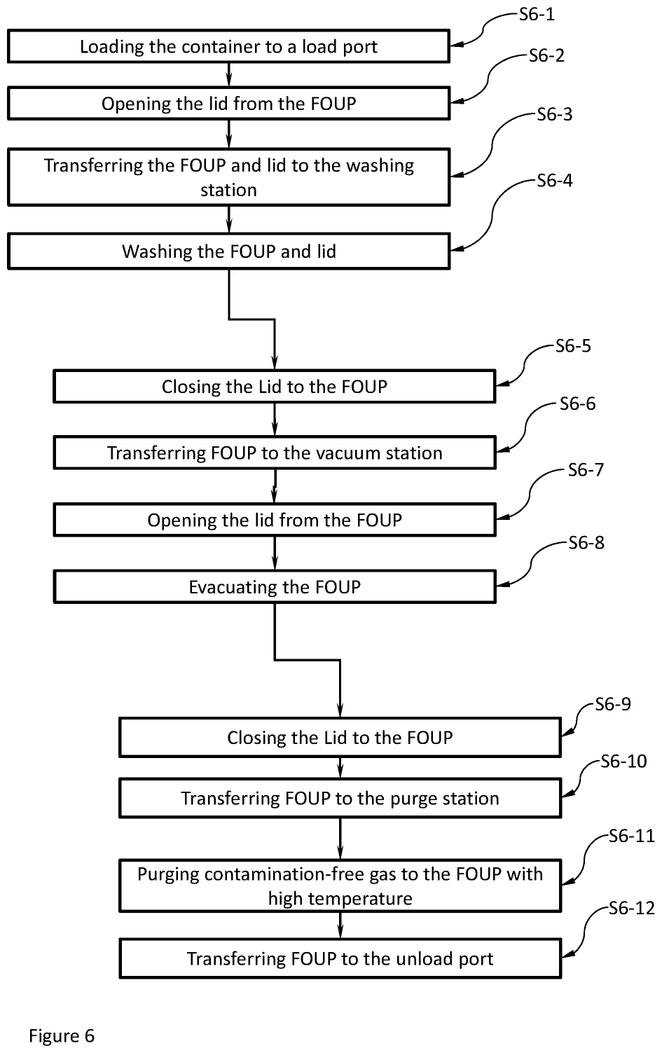

Please refer to FIG. 5 and FIG. 6, wherein FIG. 5 illustrates the FOUP cleaning system according to another embodiment of the present invention while FIG. 6 is a flow diagram showing each step for cleaning the FOUP in the cleaning system. In this embodiment, load port and unload port are not shown in order to illustrate the present invention more clearly. The cleaning system 100 includes a load port, a washing chamber 120, a vacuum chamber140, a nitrogen purging station 160, and an unload port. In the beginning, the FOUP or container is loaded into the load port as shown in step S6-1, and then the lid 2 is opened from the FOUP as shown in step S6-2. The body 1 and lid 2 are transferred to the washing chamber 120 as shown in step S6-3.

Then, the FOUP is washed in the washing chamber 120 as shown in step S6-4. Recipes and process in the washing chamber 120 is similar to the embodiment mentioned above. High temperature in washing chamber 120 and hot DI water is provided, and high gas exchange rate is also necessary. Please notice that the washing nuzzle 122 can purge both hot DI water and gas.

Then, the lid 2 is closed to the body 1 as shown in step S6-5 and both are transferred to the vacuum chamber 140 as shown in step S6-6. The lid 2 is opened again in the vacuum chamber 140 as shown in step S6-7, and then body 1 and lid 2 are evacuated in the vacuum chamber 140 through the evacuating pipe 142 at least 45° C. as shown in step S6-8.

Next, the FOUP is transferred to the nitrogen purging station. The lid 2 is closed to the body 1 as shown in step S6-9 in the vacuum chamber 140. The FOUP is transferred to the purging station 160 as shown in step S6-10. Then, the contamination-free gas is purged to the FOUP with high temperature as shown in step S6-11. Recipes and process for purging contamination-free gas is similar to the embodiment mentioned above. Then, the FOUP is transferred to the unload port as shown in step S6-12.

Please notice that contamination-free gas provided into FOUP in this embodiment experience pressure dropping inside the FOUP. However, a hot contamination-free gas is provided, and the temperature inside the FOUP can be kept relative higher to the clean room temperature. Thus, the issue incurred in the commercially available solution can be avoided.

In the present invention, the FOUP cleaning system can occupy a relatively small footprint compared to the commercially available solution. This will be important in the clean room, due to the overhead running cost of the clean room depends upon the area.

In one embodiment of the present invention, the FOUP cleaning system provides a lower cost equipment and low maintenance fee, due to no vacuum chamber.

In one embodiment of the present invention, the overall cleaning duration is shorter due to no evacuating process.

In one embodiment of the present invention, the drawback incurred by the low temperature nitrogen purging process can be avoided due to the omitted evacuating process. Even the evacuating process is applied to the present invention, the hot nitrogen gas also avoid the low temperature issue inside the FOUP at the nitrogen purging step.

In one embodiment of the present invention, a simple structure compared to the prior commercially available solution is provided. Thus, the lower BOM cost is provided.

In the present invention, VOC and AMC can be removed more seriously at the high temperature environment.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for cleaning a container, comprising:
loading a container into a cleaning system;
opening a lid of the container;
washing the container and the lid at a first temperature higher than 45° C.; and
purging the container with contamination-free gas at temperature at least higher than 45° C.

2. The method according to claim 1, wherein the washing step includes steps of:
spraying DI water to the container and the lid; and
purging gas to the container and the lid to dry the container and the lid.

3. The method according to claim 2, wherein the purging gasp step provides a gas exchange rate at least 8 cycle/min.

4. The method according to claim 3, wherein a temperature of the washing chamber is ranged from about 45-70° C.

5. The method according to claim 4, wherein a temperature of the DI water is ranged from about 45-70° C.

6. The method according to claim 1, further comprising an evacuating step between said washing step and said purging step for evacuating the container.

7. The method according to claim 6, wherein a temperature of the evacuating step is about 45° C.

8. The method according to claim 1, wherein the container is a FOUP.

9. The method according to claim 8, further comprising a step of purging the FOUP with contamination-free gas at a clean room temperature.

10. A system for cleaning a container, comprising:
a load port for loading the container and opening a lid of the container;
a washing chamber, receiving the container and the lid from the load port, for washing the container with a first nuzzle and a second nuzzle, wherein the first nuzzle sprays a beam of DI water to the container and the lid, and a second nuzzle purges a gas flow to dry the container;
an unload port, receiving the container from the washing chamber, for purging the container with contamination-free gas; and
a heating element for controlling temperatures of the washing chamber, the first nuzzle, the second nuzzle, and the contamination-free gas.

11. The system according to claim 10, wherein the second nuzzle provides a gas exchange rate at least 8 cycle/min.

12. The system according to claim 11, wherein the temperature of the washing chamber is kept above 45° C.

13. The system according to claim 12, wherein the temperature of the beam of DI water is kept above 45° C.

14. The system according to claim 13, wherein the temperature of the second nuzzle is kept above 45° C.

15. The system according to claim 14, wherein the temperature of the contamination-free gas is kept above 45° C.

16. The system according to claim 10, further comprising a vacuum chamber for receiving the container and the lid from the washing chamber to evacuating the container and the lid.

17. The system according to claim 16, wherein the heating element control a temperature of the vacuum chamber.

18. The system according to claim 17, wherein the temperature of the vacuum chamber is kept above 45° C.

19. The system according to claim 10, wherein the container is a FOUP.
